(19) United States
(12) Patent Application Publication
(10) Pub. No.: US 2025/0308936 A1
(43) Pub. Date: Oct. 2, 2025

(54) COAXIAL VIA FORMATION WITH SIDEWALL CONTACTS

(71) Applicant: International Business Machines Corporation, Armonk, NY (US)

(72) Inventors: Nilanka W. Sirikkathuge, Guilderland, NY (US); Tao Li, Slingerlands, NY (US); Joshua M. Rubin, Albany, NY (US); Qianwen Chen, Chappaqua, NY (US); Ruilong Xie, Niskayuna, NY (US)

(21) Appl. No.: 18/624,206

(22) Filed: Apr. 2, 2024

(51) Int. Cl. H01L 21/48; H01L 23/00; H01L 23/538

(52) U.S. Cl. CPC H01L 21/486; H01L 23/5384; H01L 24/16; H01L 24/32; H01L 24/73; H01L 2224/16225; H01L 2224/32225; H01L 2224/73204

(57) ABSTRACT

Embodiments of the present disclosure relate to coaxial through silicon vias (TSV) and/or through insulator vias (TIV) with sidewall contacts on both the top and bottom. A technique includes forming a coaxial via having an outer conductor surrounding an inner conductor, the outer conductor being separated from the inner conductor by a dielectric material, the coaxial via formed through a through material so as to have a first end opposite a second end. The technique includes forming a first contact connected to the outer conductor at the first end and forming a second contact connected to the outer conductor at the second end.

### BACKGROUND

The present disclosure generally relates to fabrication methods and resulting structures for integrated circuits (ICs), and more specifically, to fabrication methods and resulting structures for coaxial through silicon vias (TSV) and/or through insulator vias (TIV) with sidewall contacts on both the top and bottom.

ICs (also referred to as a chip or a microchip) include electronic circuits on a wafer. The wafer is a semiconductor material, such as, for example, silicon or other materials. An IC is formed of a large number of devices, such as transistors, capacitors, resistors, etc., which are formed in layers of the IC and interconnected with wiring in the back-end-of-line (BEOL) layers of the wafer. Typical ICs are formed by first fabricating individual semiconductor devices using processes referred to generally as the front-end-of-line (FEOL).

### SUMMARY

Embodiments of the present disclosure are directed to coaxial through silicon vias (TSV) and/or through insulator vias (TIV) with sidewall contacts on both the top and bottom. A non-limiting method of forming a semiconductor structure includes forming a coaxial via having an outer conductor surrounding an inner conductor, the outer conductor being separated from the inner conductor by a dielectric material, the coaxial via formed through a through material so as to have a first end opposite a second end. The method includes forming a first contact connected to the outer conductor at the first end and forming a second contact connected to the outer conductor at the second end.

According to one or more embodiments, a non-limiting semiconductor structure includes a through material and a coaxial via including an outer conductor surrounding an inner conductor, the outer conductor being separated from the inner conductor by a dielectric material, the coaxial via being formed through the through material so as to have a first end opposite a second end. The device includes a first conductive via electrically coupled to the outer conductor at the first end, where the first conductive via electrically couples the coaxial via to a device layer. The device includes a second conductive via electrically coupled to the outer conductor at the second end.

Other embodiments of the present disclosure implement features of the above-described devices/structures in methods and/or implement features of the methods in devices/structures.

Additional technical features and benefits are realized through the techniques of the present disclosure. Embodiments and aspects of the disclosure are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the disclosure are apparent from the following detailed description taken in conjunction with the accompanying drawings in which:

FIG. 1 depicts a cross-sectional view of a portion of an integrated circuit (IC) under-fabrication according to one or more embodiments;

FIG. 2 depicts a cross-sectional view of a portion of an IC under-fabrication after fabrication operations according to one or more embodiments;

FIG. 3 depicts a cross-sectional view of a portion of an IC under-fabrication after fabrication operations according to one or more embodiments;

FIG. 4 depicts a cross-sectional view of a portion of an IC under-fabrication after fabrication operations according to one or more embodiments;

FIG. 5 depicts a cross-sectional view of a portion of an IC under-fabrication after fabrication operations according to one or more embodiments;

FIG. 6 depicts a cross-sectional view of a portion of an IC under-fabrication after fabrication operations according to one or more embodiments;

FIG. 7 depicts a cross-sectional view of a portion of an IC under-fabrication after fabrication operations according to one or more embodiments;

FIG. 8 depicts a cross-sectional view of a portion of an IC under-fabrication after fabrication operations according to one or more embodiments;

FIG. 9 depicts a cross-sectional view of a portion of an IC under-fabrication after fabrication operations according to one or more embodiments;

FIG. 10 depicts a cross-sectional view of a portion of an IC under-fabrication after fabrication operations according to one or more embodiments;

FIG. 11 depicts a cross-sectional view of a portion of an IC under-fabrication after fabrication operations according to one or more embodiments;

FIG. 12 depicts a cross-sectional view of a portion of an IC under-fabrication after fabrication operations according to one or more embodiments;

FIG. 13A depicts a cross-sectional view of a portion of an IC under-fabrication after fabrication operations according to one or more embodiments;

FIG. 13B depicts a cross-sectional view of a portion of an IC under-fabrication after fabrication operations according to one or more embodiments;

FIG. 14 depicts a cross-sectional view of a portion of an IC under-fabrication after fabrication operations according to one or more embodiments;

FIG. 15 depicts a cross-sectional view of a portion of an IC under-fabrication after fabrication operations according to one or more embodiments;

FIG. 16 depicts a cross-sectional view of a portion of an IC under-fabrication after fabrication operations according to one or more embodiments;

FIG. 17 depicts a cross-sectional view of a portion of an IC under-fabrication after fabrication operations according to one or more embodiments;

FIG. 18 depicts a cross-sectional view of a portion of an IC under-fabrication after fabrication operations according to one or more embodiments;

FIGS. 19A and 19B depict cross-sectional views of a portion of an IC under-fabrication after optional fabrication operations according to one or more embodiments;

FIG. 20 depicts a cross-sectional view of a portion of an IC under-fabrication after fabrication operations according to one or more embodiments;

FIG. 21 depicts a cross-sectional view of a portion of an IC under-fabrication after fabrication operations according to one or more embodiments;

FIG. 22 depicts a cross-sectional view of a portion of an IC under-fabrication after fabrication operations according to one or more embodiments;

FIG. 23 depicts a cross-sectional view of a portion of an IC under-fabrication after fabrication operations according to one or more embodiments;

FIG. 24 depicts a cross-sectional view of a portion of an IC under-fabrication after fabrication operations according to one or more embodiments;

FIG. 25 depicts a cross-sectional view of a portion of an IC under-fabrication after fabrication operations according to one or more embodiments;

FIG. 26 depicts a cross-sectional view of a portion of an IC under-fabrication after fabrication operations according to one or more embodiments;

FIG. 27 depicts a cross-sectional view of a portion of an IC under-fabrication after fabrication operations according to one or more embodiments;

FIG. 28 depicts a cross-sectional view of a portion of an IC under-fabrication after fabrication operations according to one or more embodiments;

FIG. 29 depicts a cross-sectional view of a portion of an IC under-fabrication after fabrication operations according to one or more embodiments;

FIGS. 30A, 30B, 30C, 30D, 20E, and 30F depict cross-sectional views of a portion of an IC under-fabrication after alternate fabrication operations according to one or more embodiments;

FIG. 31 depicts a flowchart of a method of forming a semiconductor structure according to one or more embodiments; and

FIG. 32 depicts a flowchart of a method of forming a semiconductor structure according to one or more embodiments.

### DETAILED DESCRIPTION

One or more embodiments provide coaxial through silicon vias (TSV) and/or through insulator vias (TIV) with sidewall contacts on both the top and bottom. The coaxial TSV and/or coaxial TIV may be referred to as coaxial vias. The coaxial TIV and/or the coaxial TSV with sidewall contacts to the cladding on top and bottom of the TIV or TSV provide a continuous and complete shielding effect, according to one or more embodiments. The cladding refers to the outer conductor. The sidewall contact to the cladding overlaps a dielectric liner on the sidewall of the cladding. For the coaxial TSV, a sidewall contact to the cladding overlaps a dielectric liner on the sidewall of the cladding and a planar dielectric layer adjacent to the silicon substrate. The sidewall contacts can be made through subtractive or damascene processes, which influence the sidewall angle at the edge of the metal features. The coaxial via with sidewall contact can be part of an interposer, three-dimensional (3D) chip, and/or fanout package.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

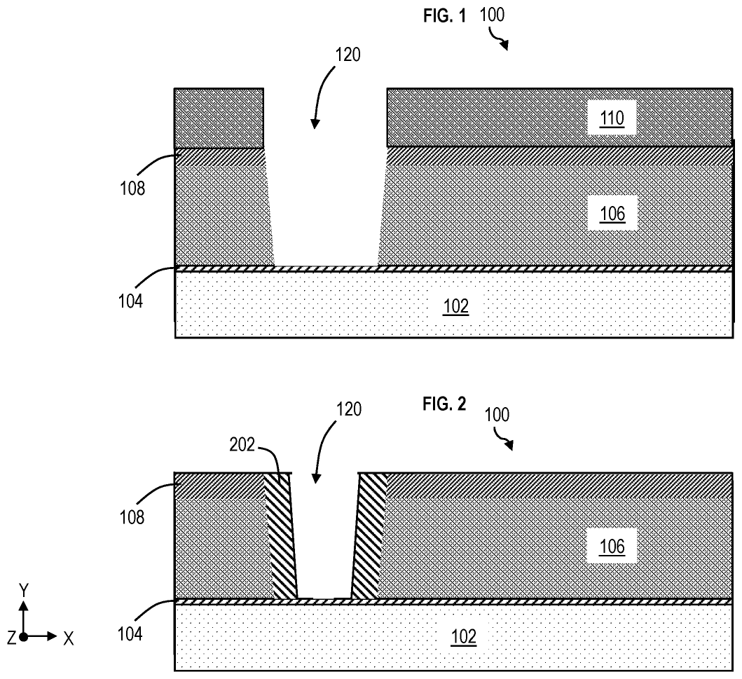

Turning now to a more detailed description of aspects of the present disclosure, FIG. 1 depicts a cross-sectional view of a portion of an integrated circuit (IC) 100 according to one or more embodiments. Standard semiconductor fabrication techniques can be utilized to fabricate the IC as understood by one of ordinary skill in the art. Any suitable lithography processes including deposition techniques and etching techniques can be utilized herein.

FIG. 1 depicts the IC 100 having a wafer as a substrate 102, a release layer 104 formed on the substrate 102, a dielectric layer 106 formed on the release layer 104, and a metal layer 108 formed on the dielectric layer 106. A hardmask layer 110 is formed on the metal layer 108 and patterned using any suitable technique. Lithography may be utilized to pattern the hardmask layer 110, for example, using a patterned photoresist material. Etching, such as reactive ion etching (RIE), is performed to transfer the pattern in the hardmask layer 110 into the metal layer 108 and dielectric layer 106 resulting in cavity 120, which stops on the release layer 104.

The wafer or substrate 102 may be formed of (pure) silicon. Other suitable materials can be utilized for the substrate 102. The dielectric layer 106 can include one or more suitable materials including dielectric organic materials, dielectric inorganic materials, polymers, low-k dielectric materials, ultra-low-k dielectric materials, etc. The dielectric layer 106 may include silicon dioxide or any other type of oxide.

The metal layer 108 can include any suitable materials including copper, aluminum, gold, etc. Other metals can be utilized for the metal layer 108. The hardmask layer 110 can be a single layer or hardmask stack. Example materials for the hardmask layer 110 can include one or more layers of amorphous carbon, organo siloxane based materials, silicon nitride (SiN), silicon oxynitride (SiON), titanium nitride (TiN), etc. The release layer 104 can include suitable materials for releasing the carrier, for example, substrate 102. Example materials of the release layer 104 may include standard inorganic dielectric materials such as oxides. The release layer 104 can include spin-on polymers, etc.

FIG. 2 depicts a cross-sectional view of the IC 100 after hardmask removal, metal layer deposition, and break through. Metal is conformally deposited and then etching is performed to form outer conductor 202. Lithography can be utilized to perform the etching, and etching continues to expose the release layer 104. As result, the outer conductor 202 is formed on sidewalls of the cavity 120. The outer conductor 202 may be referred to as the cladding for a coaxial via. The metal of the outer conductor 202 can be formed of any suitable materials including the materials discussed for the metal layer 108.

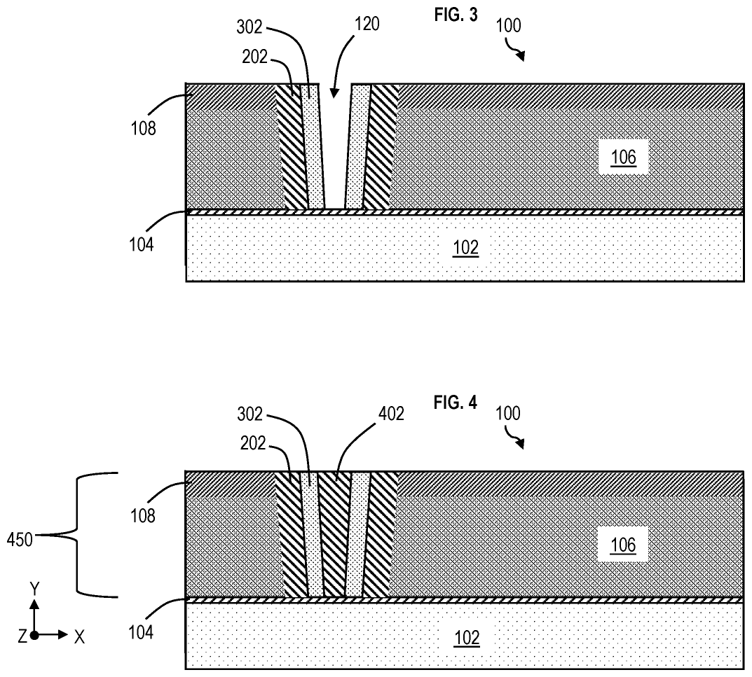

FIG. 3 depicts a cross-sectional view of the IC 100 after dielectric layer deposition and break through. Dielectric material is deposited and etching is performed to form dielectric layer 302 in the cavity 120. After patterning using lithography, the dielectric layer 302 remains on the sidewalls of the cavity 120, with the release layer 104 exposed. The dielectric layer 302 may include any suitable materials including one or more example materials discussed for dielectric layer 106. The dielectric layer 302 can include oxides, nitrides, etc.

FIG. 4 depicts a cross-sectional view of the IC 100 after metal deposition. Metal is deposited to fill the remaining space of the cavity 120, and etching is performed to etch back the metal in order to form inner conductor 402. The inner conductor 402 can be referred to as the core of the coaxial via while the outer conductor 202 can be referred to as the cladding as noted herein. Examples materials of the inner conductor 402 may include the metals utilized to form the outer conductor 202 and/or the metal layer 108. In one or more embodiments, the inner conductor 402 and the outer conductor 202 may be formed of different materials from the metal layer 108.

As can be seen in FIG. 4, a coaxial via 450 has been formed as a through insulator via (TIV). The coaxial via 450 is through the insulator material of the dielectric layer 106. The coaxial via 450 includes the inner conductor 402 surrounded by the outer conductor 202. The dielectric material of the dielectric layer 302 separates the inner conductor 402 and outer conductor 202 in the coaxial via 450.

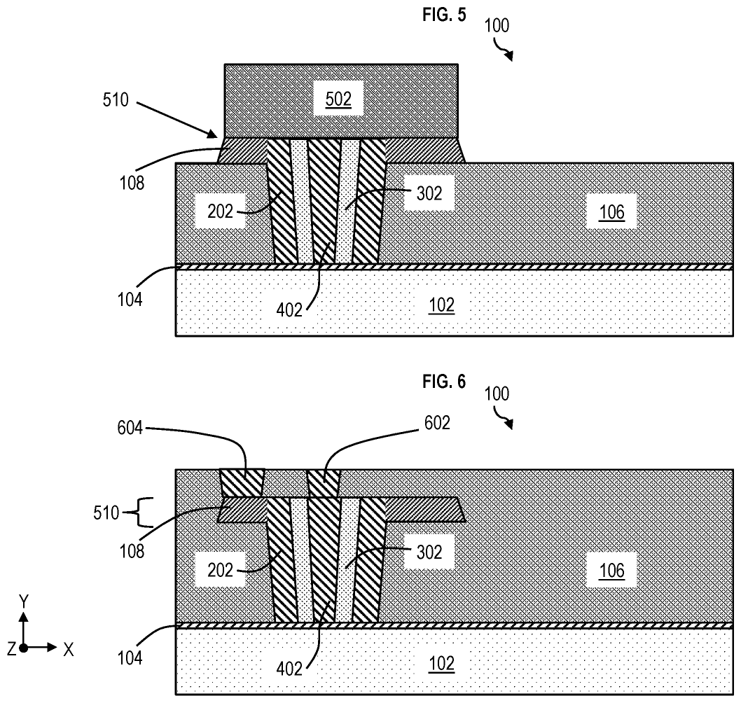

FIG. 5 depicts a cross-sectional view of the IC 100 after through insulator via (TIV) top footing patterning and subtractive metal etching. A hardmask layer 502 is deposited and patterned. The material of the hardmask layer 502 can include any suitable materials including materials discussed for hardmask layer 110. Using lithography, the pattern of the hardmask layer 502 is utilized to etch the metal layer 108 into a top contact 510 (e.g., first contact), where the top contact 510 serves as a top footing on the dielectric layer 106 after portions of the metal layer 108 are removed. In one or more embodiments, a damascene process may be utilized to form the top contact 510 of the metal layer 108 instead of a subtractive metal etch.

FIG. 6 depicts a cross-sectional view of the IC 100 after hardmask removal, additional dielectric layer fill, and conductive via formation. Additional dielectric material of the dielectric layer 106 is deposited, and openings exposing the inner conductor 402 and the metal layer 108 (e.g., top contact 510) are etched through the dielectric layer 106, using lithography. Metal is deposited to fill the openings, and etch back is performed, resulting in conductive via 602 in contact with the inner conductor 402 and conductive via 604 in contact with the metal layer 108 (e.g., top contact 510). Although one conductive via 604 is shown on the metal layer 108, another conductive via 604 can be formed on the metal layer 108 (e.g., top contact) on the other side of the conductive via 602. Example metals of conductive via 602 and conductive via 604 can include any of the metals discussed herein for the inner conductor 402, outer conductor 202, and metal layer 108.

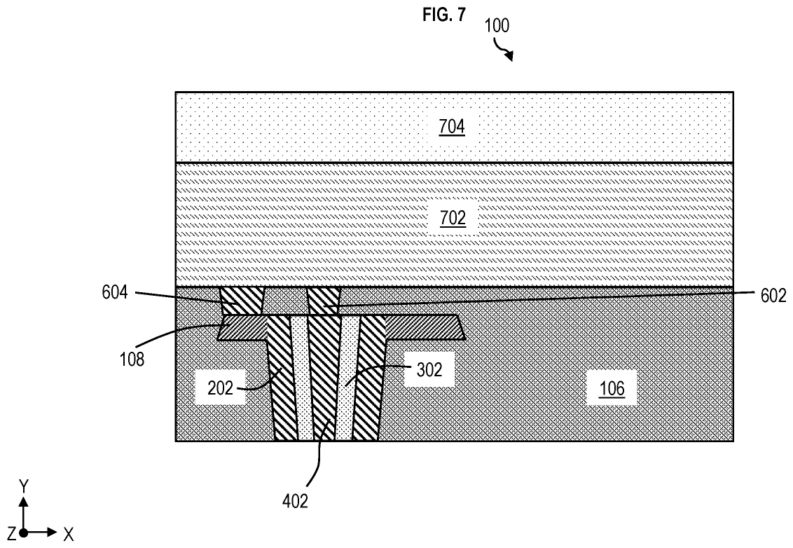

FIG. 7 depicts a cross-sectional view of the IC 100 after device layer attachment, carrier bonding, and debonding of the carrier on the opposite side. Using suitable techniques, a device layer 702 is attached to a surface on one side of the IC 100, and a carrier substrate 704 is attached to the device layer 702. The device layer 702 can include various devices and interconnects as understood by one of ordinary skill in the art. The substrate 102 (e.g., carrier) and release layer 104 have been removed from the opposite side of the IC 100, exposing the surface for further fabrication processing.

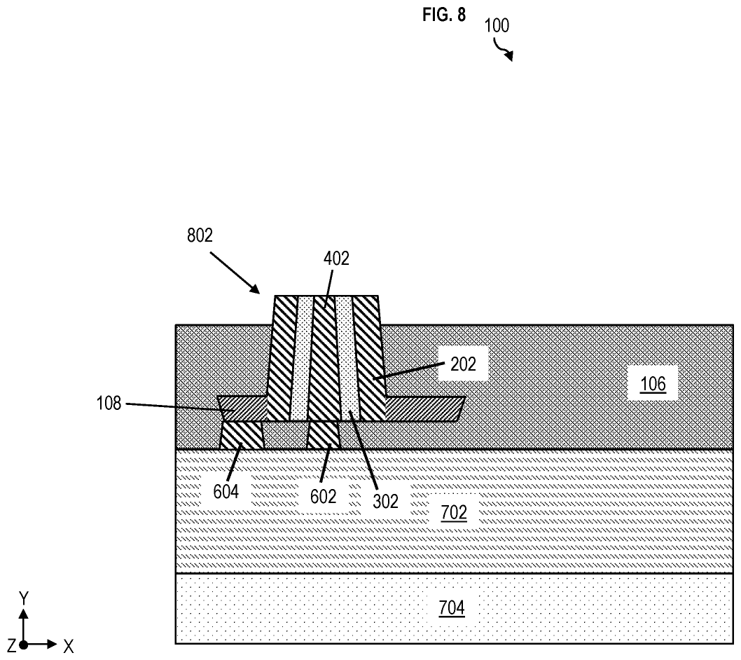

FIG. 8 depicts a cross-sectional view of the IC 100 after a wafer flip and dielectric recess. The dielectric layer 106 is selectively recessed, exposing one end 802 of the coaxial via. The dielectric layer 302 and the dielectric layer 106 can be different materials, such that the dielectric layer 106 can be selectively etched. In one or more embodiments, a block mask can be utilized to protect the coaxial via while the dielectric layer 106 is selectively removed.

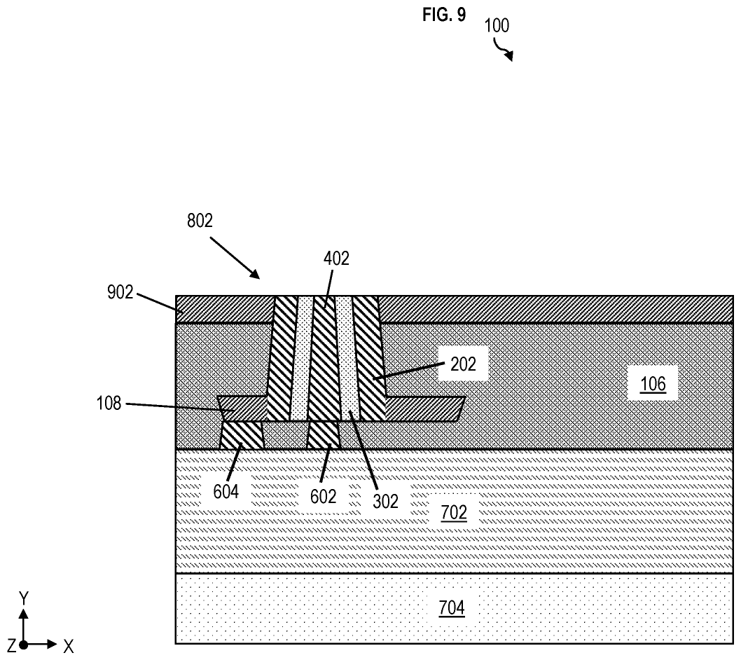

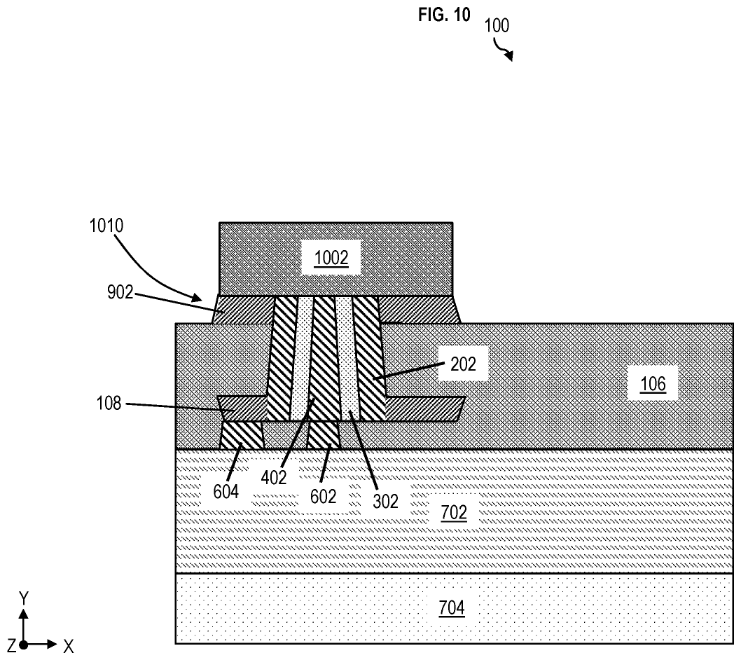

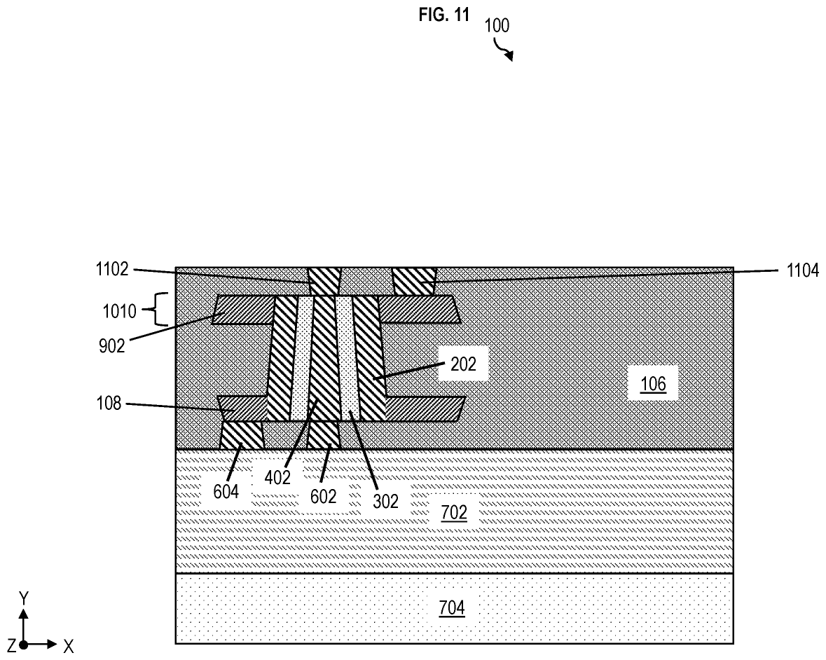

FIG. 9 depicts a cross-sectional view of the IC 100 after metal deposition and planarization. A metal layer 902 is deposited, and planarization is performed to expose the tops of the coaxial via at one end 802. The metal layer 902 is in contact with the outer conductor 202 in order to serve as a bottom contact 1010 depicted in FIG. 10. It is noted that the exposed outer conductor 202 has a small dimension in the x-axis. In one or more embodiments, the thickness of the outer conductor 202 in the x-axis can be about 10 nanometers (nm), 15 nm, 20 nm, 30 nm, 50 nm, etc. In one or more embodiments, the thickness in the x-axis of the outer conductor 202 can range from about 10-100 nm. The small dimension of the outer conductor 202 may present a challenge to form a conductive via on the surface of the outer conductor 202, and therefore, forming the metal layer 902 to be a bottom contact 1010 for conductive via 1104 (e.g., depicted in FIG. 11) addresses this issue, as discussed herein.

FIG. 10 depicts a cross-sectional view of the IC 100 after through insulator via (TIV) bottom footing patterning and subtractive metal etching. It is noted that the bottom side of the IC 100 is facing upward for processing. A hardmask layer 1002 is deposited and patterned. The material of the hardmask layer 1002 can include any suitable materials including materials discussed for hardmask layers 110 and 502. Using lithography, the pattern of the hardmask layer 1002 is utilized to etch the metal layer 902 into a bottom contact 1010 (e.g., second contact), where the bottom contact 1010 serves as a bottom footing on the dielectric layer 106 after portions of the metal layer 902 have been removed. In one or more embodiments, a damascene process may be utilized to form the bottom contact 1010 of the metal layer 902 instead of a subtractive metal etch.

FIG. 11 depicts a cross-sectional view of the IC 100 after hardmask removal, additional dielectric layer fill, and conductive via formation. After the hardmask layer 1002 is removed, additional dielectric material of the dielectric layer 106 is deposited and openings exposing the inner conductor 402 and the metal layer 108 (e.g., top contact 510) are etched through the dielectric layer 106, using lithography. Metal is deposited to fill the openings, and etch back is performed, resulting in conductive via 1102 in contact with the inner conductor 402 and conductive via 1104 in contact with the metal layer 902 (e.g., bottom contact 1010). Although one conductive via 1104 is shown on the metal layer 902, another conductive via 1104 can be formed on the metal layer 902 (e.g., bottom contact 1010) on the other side of the conductive via 1102. Example metals of conductive via 1102 and conductive via 1104 can include any of the metals discussed herein for the inner conductor 402, outer conductor 202, metal layer 108, and metal layer 902.

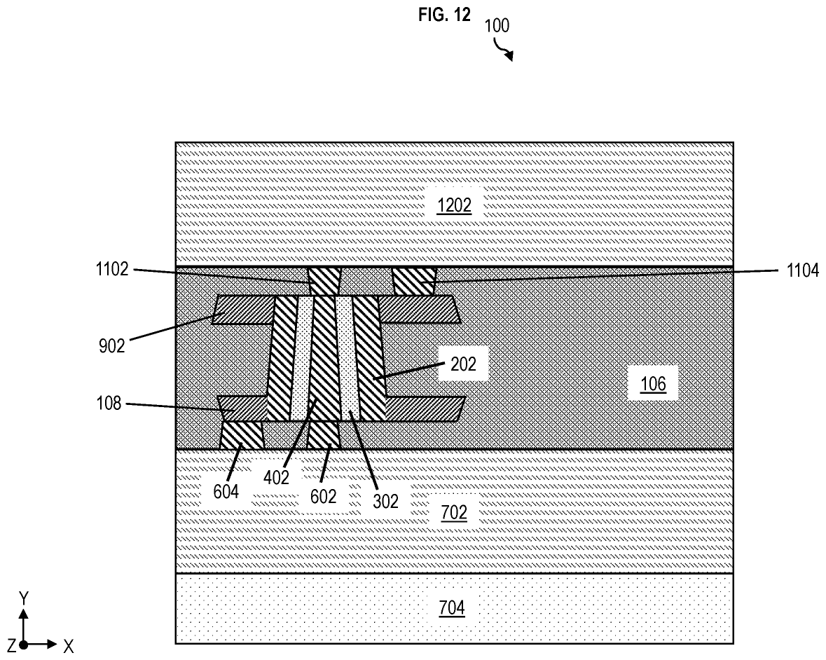

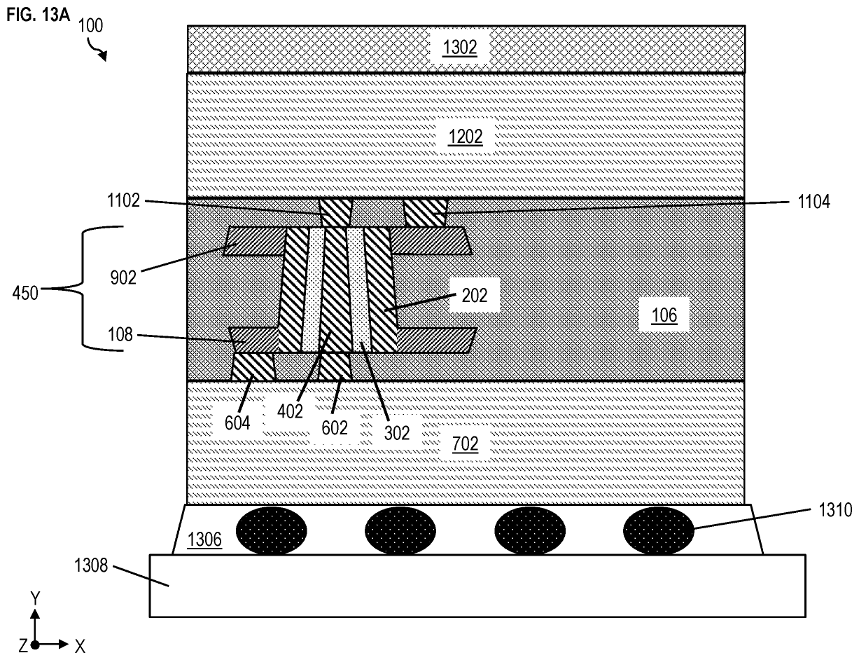

FIG. 12 depicts a cross-sectional view of the IC 100 after device layer attachment. Using suitable techniques, a device layer 1202 is attached to a surface on one side of the IC 100. The device layer 1202 can include various devices and interconnects as understood by one of ordinary skill in the art.

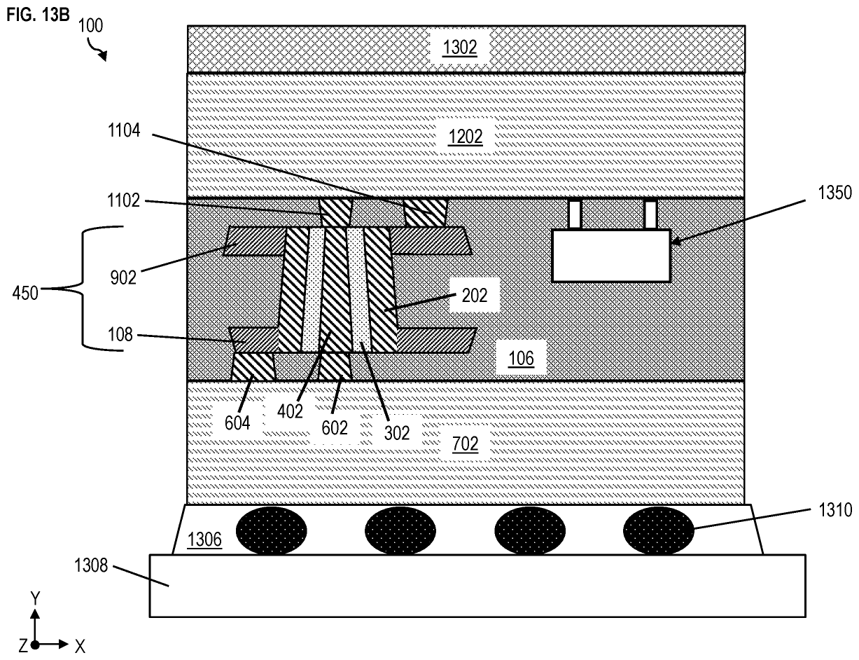

FIG. 13A depicts a cross-sectional view of the IC 100 after controlled collapse chip connection (C4) bump formation, package attachment, carrier detachment, and lid attachment. The carrier 704 is detached. A C4 bump layer 1306 of C4 bumps 1310 is attached to the device layer 702, and a package 1308 is attached to the C4 bumps 1310. The C4 bumps can include soldering material. The package 1308 can include a printed circuit board. The C4 bumps and package can be part of a flip chip package. A lid 1302 can be attached to the device layer 1202. In one or more embodiments, the lid 1302 can be attached to the package 1308 as understood by one of ordinary skill in the art. FIG. 13B depicts a cross-sectional view of the IC 100 where one or more active devices 1350 (ICs, chips, etc.) are identified adjacent to the coaxial via 450. The active devices 1350 can be formed by an suitable techniques as understood by one of ordinary skill in the art.

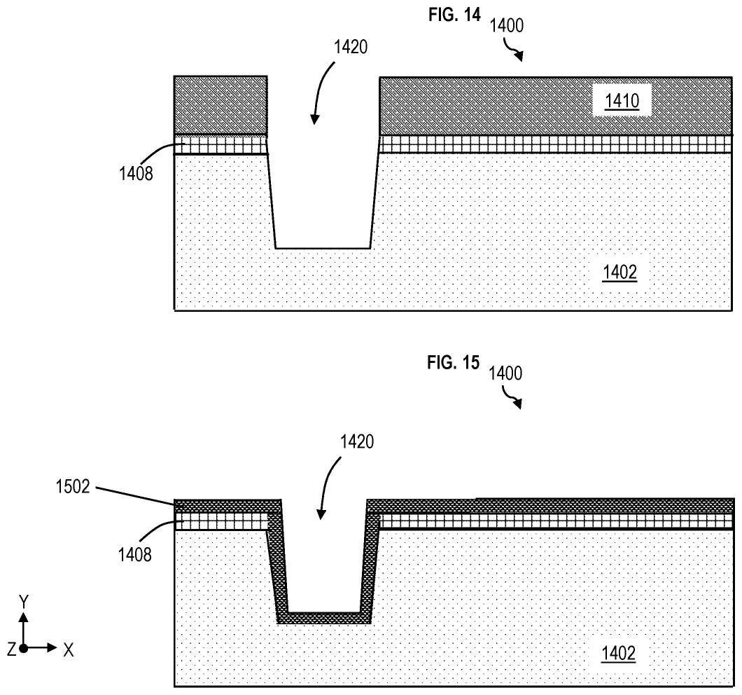

According to one or more embodiments of the present disclosure, FIG. 14 depicts a cross-sectional view of a portion of an integrated circuit (IC) 1400 according to one or more embodiments. Standard semiconductor fabrication techniques can be utilized to fabricate the IC as understood by one of ordinary skill in the art. Any suitable lithography processes including deposition techniques and etching techniques can be utilized herein. Some fabrication processes of the IC 100 can be applied by analogy to the IC 1400.

FIG. 14 depicts the IC 1400 having a wafer as a substrate 1402, an optional insulator layer 1408 formed on the substrate 1402, and a hardmask layer 1410 formed on optional insulator layer 1408. When the optional insulator layer 1408 is not present, the hardmask layer 1410 can be formed on the substrate 1402. The hardmask layer 1410 is patterned using any suitable technique. Lithography may be utilized to pattern the hardmask layer 1410, for example, using a patterned photoresist material. Etching, such as a RIE etch, is performed to transfer the pattern in the hardmask layer 1410 into the optional insulator layer 1408 and substrate 1402 resulting in cavity 1420.

The wafer or substrate 102 may be formed of (pure) silicon. Other suitable materials can be utilized for the substrate 102. The optional insulator layer 1408 may include one or more suitable materials including dielectric organic materials, dielectric inorganic materials, polymers, low-k dielectric materials, ultra-low-k dielectric materials, etc. The optional insulator layer 1408 may include silicon dioxide or any other type of oxide. The hardmask layer 1410 can be a single layer or hardmask stack. Example materials for the hardmask layer 1410 can include one or more layers of amorphous carbon, organo siloxane based materials, silicon nitride (SiN), silicon oxynitride (SiON), titanium nitride (TiN), etc.

FIG. 15 depicts a cross-sectional view of the IC 1400 after hardmask removal and dielectric layer deposition. A dielectric material is deposited to be an isolation shielding layer from the substrate 1402, resulting in a dielectric layer 1502. The dielectric layer 1502 can include one or more dielectric materials including materials discussed for the optional insulator layer 1408.

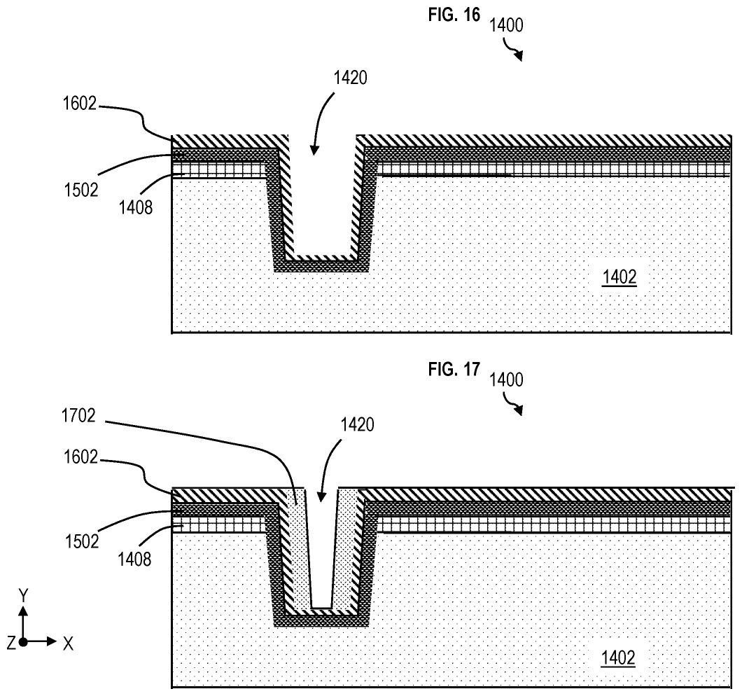

FIG. 16 depicts a cross-sectional view of the IC 1400 after conformal deposition of metal. Metal of a metal layer 1602 is deposited on the dielectric layer 1502. The metal layer 1602 can include any suitable materials including copper, aluminum, gold, etc. The metal layer 1602 on the sidewalls of the cavity 1420 will serve as the material for the outer conductor.

FIG. 17 depicts a cross-sectional view of the IC 1400 after dielectric layer deposition and break through. Dielectric material is deposited, and etching is performed to form dielectric layer 1702 in the cavity 1420. After patterning using lithography, the dielectric layer 1702 remains on the sidewalls of the cavity 1420, with the metal layer 1602 exposed at the bottom. The dielectric layer 1702 may include any suitable materials including one or more example materials discussed for dielectric layer 1502. The dielectric layer 1702 can include oxides, nitrides, etc.

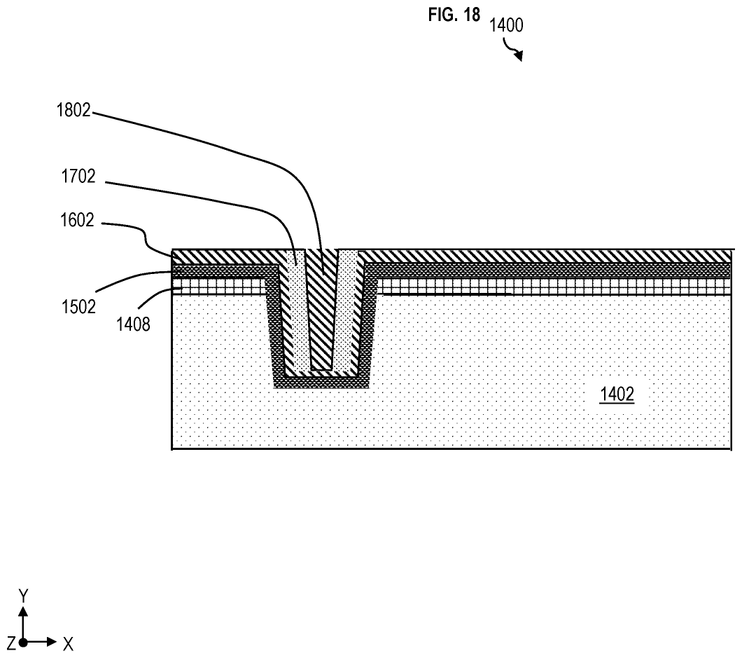

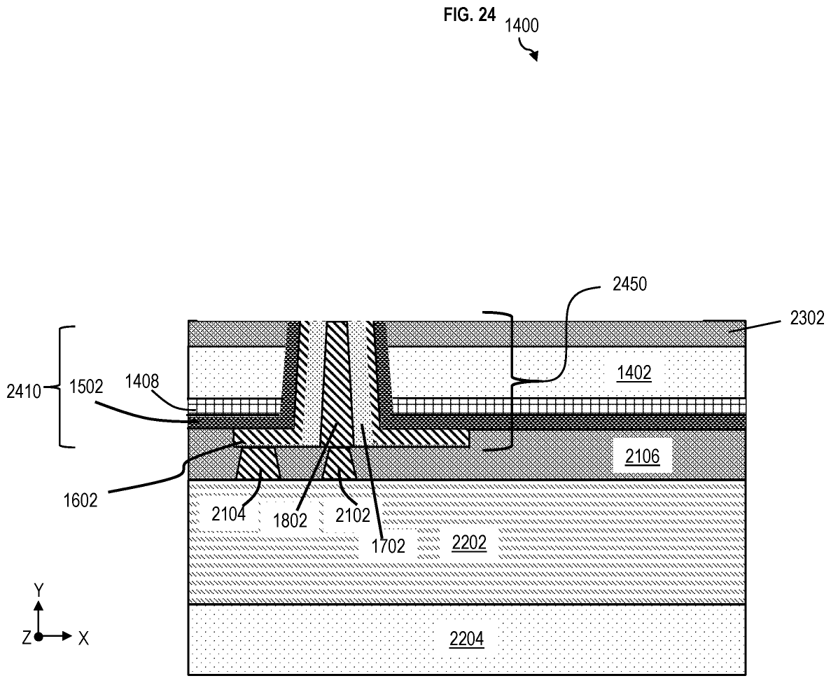

FIG. 18 depicts a cross-sectional view of the IC 1400 after metal deposition. Metal is deposited to fill the remaining space of the cavity 1420, and etching is performed to etch back the metal in order to form inner conductor 1802. The inner conductor 1802 can be referred to as the core of the coaxial via while an outer conductor 2410 (e.g., depicted in FIG. 24) can be referred to as the cladding as noted herein. Example materials of the inner conductor 1802 and the outer conductor 202 may include any suitable materials including copper, aluminum, gold, etc. In one or more embodiments, the inner conductor 402 and the outer conductor 202 may be formed of different materials from each other.

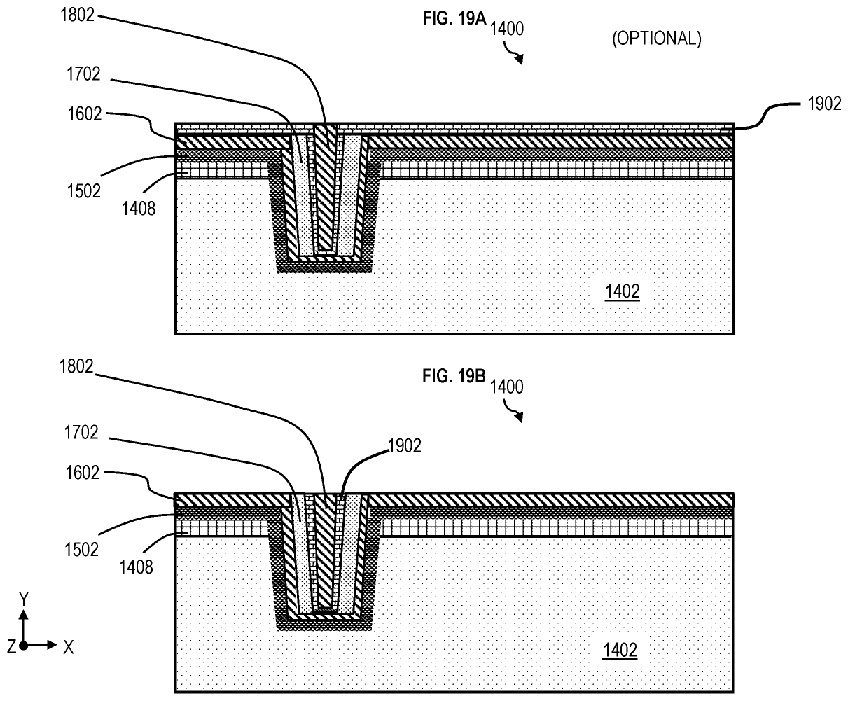

FIGS. 19A and 19B depict cross-sectional views of the IC 1400 that illustrate an optional liner according to one or more embodiments. FIGS. 19A and 19B may be performed in place of the fabrication processes in FIG. 18. Starting from FIG. 17, FIG. 19A depicts a variation in which an optional liner 1902 is conformally deposited so as to separate the inner conductor 1802 from the outer conductor 202. The inner conductor 1802 can then be formed as discussed in FIG. 18. FIG. 19B depicts the IC 1400 after polishing back the top of the inner conductor 1802 to be flush with the adjacent planar metal of the metal layer 1602, or the inner conductor 1802 may protrude above the metal layer 1602 if desired.

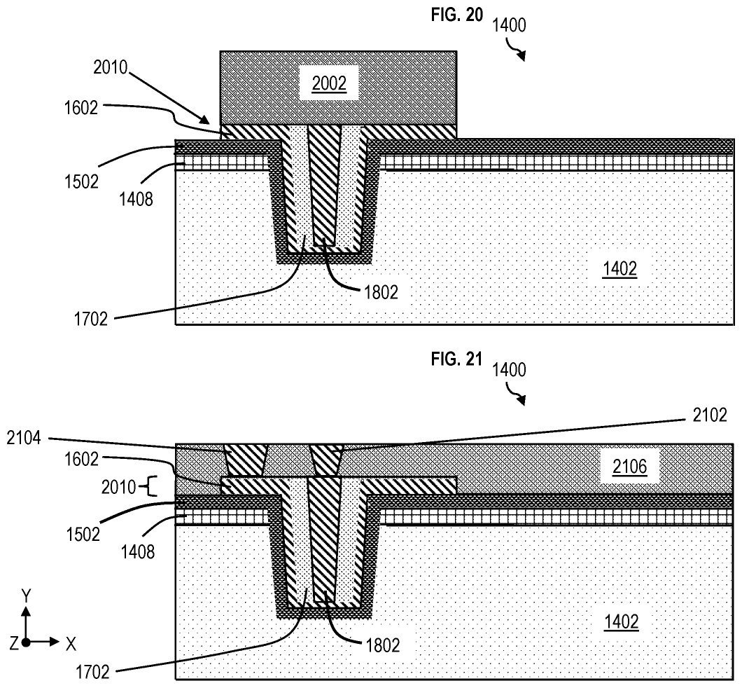

Now continuing the fabrication process which could optionally include the optional liner 1902 in one or more embodiments although not shown in subsequent figures, FIG. 20 depicts a cross-sectional view of the IC 1400 after through insulator via (TIV) top footing patterning and subtractive metal etching. A hardmask layer 2002 is deposited and patterned. The material of the hardmask layer 2002 can include any suitable materials including materials discussed for hardmask layer 1410. Using lithography, the pattern of the hardmask layer 2002 is utilized to etch the metal layer 1602 into a top contact 2010 (e.g., first contact), where the top contact 2010 serves as a top footing on the dielectric layer 1502 after portions of the metal layer 1602 have been removed. In one or more embodiments, a damascene process may be utilized to form the top contact 2010 of the metal layer 1602 instead of a subtractive metal etch.

FIG. 21 depicts a cross-sectional view of the IC 1400 after hardmask removal, additional dielectric layer fill, and conductive via formation. After removing the hardmask layer 2002, additional dielectric material of the dielectric layer 2106 is deposited and openings exposing the inner conductor 1802 and the metal layer 1602 (e.g., top contact 2010) are etched through the dielectric layer 2106, using lithography. Metal is deposited to fill the openings, and etch back is performed, resulting in conductive via 2102 in contact with the inner conductor 1802 and conductive via 2104 in contact with the metal layer 1602 (e.g., top contact 2010). Although one conductive via 2104 is shown on the metal layer 1602, another conductive via 2104 can be formed on the metal layer 1602 (e.g., top contact) on the other side of the conductive via 2102. Example metals of conductive via 2102 and conductive via 2104 can include any of the metals discussed herein for the inner conductor 1802, outer conductor 2410 (e.g., depicted in FIG. 24), and metal layer 1602.

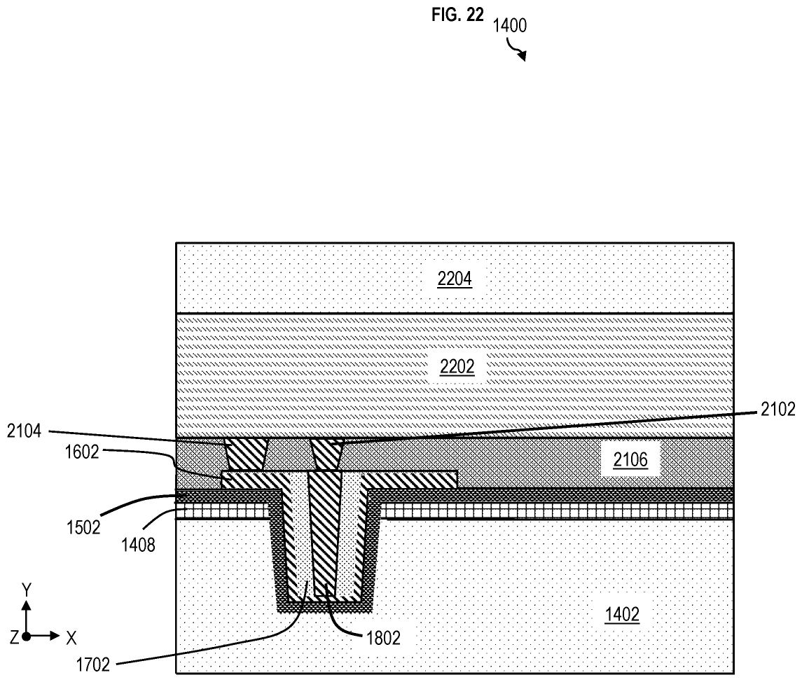

FIG. 22 depicts a cross-sectional view of the IC 1400 after device layer attachment and carrier bonding. Using suitable techniques, a device layer 2202 is attached to a surface on one side of the IC 1400, and a carrier 2204 is attached to the device layer 2202. The device layer 2202 can include various devices and interconnects as understood by one of ordinary skill in the art.

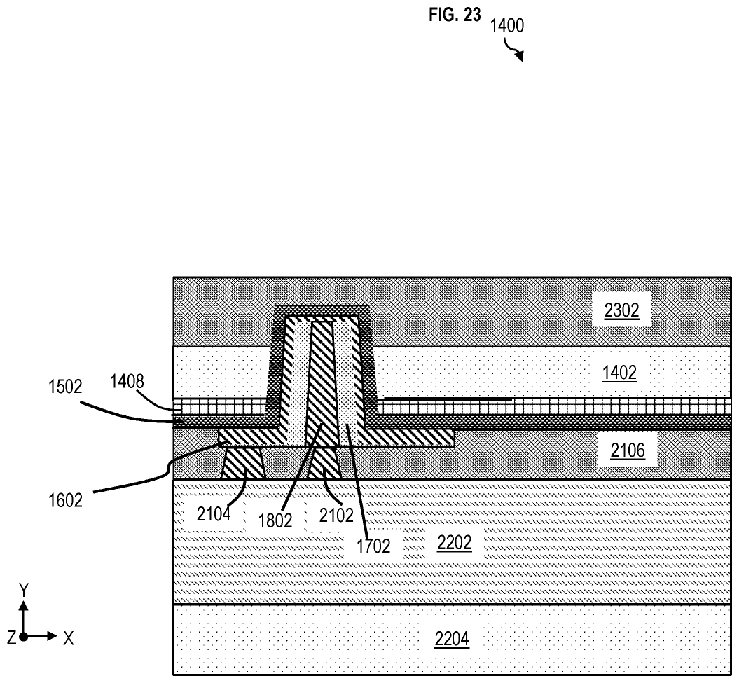

FIG. 23 depicts a cross-sectional view of the IC 1400 after a wafer flip/carrier flip exposing the backside of the substrate, substrate recess to reveal the through silicon via (TSV) end, and dielectric deposition. The substrate 1402 is selectively recessed, exposing an end of the coaxial TSV, and dielectric material is deposited to form dielectric layer 2302, which can include the same example materials of dielectric layer 2106.

FIG. 24 depicts a cross-sectional view of the IC 1400 after planarization. A non-selective etch or chemical mechanical polishing/planarization can be performed to expose the outer conductor 2410 (e.g., cladding) and inner conductor 1802 (e.g., core). As can be seen in FIG. 24, a coaxial via 2450 has been formed as a through silicon via (TSV). The coaxial via 2450 includes the inner conductor 1802 surrounded by the outer conductor 2410. The dielectric material of the dielectric layer 1702 separates the inner conductor 1802 and outer conductor 2410 in the coaxial via 2450. The coaxial via 2450 is through the silicon material of the substrate 1402.

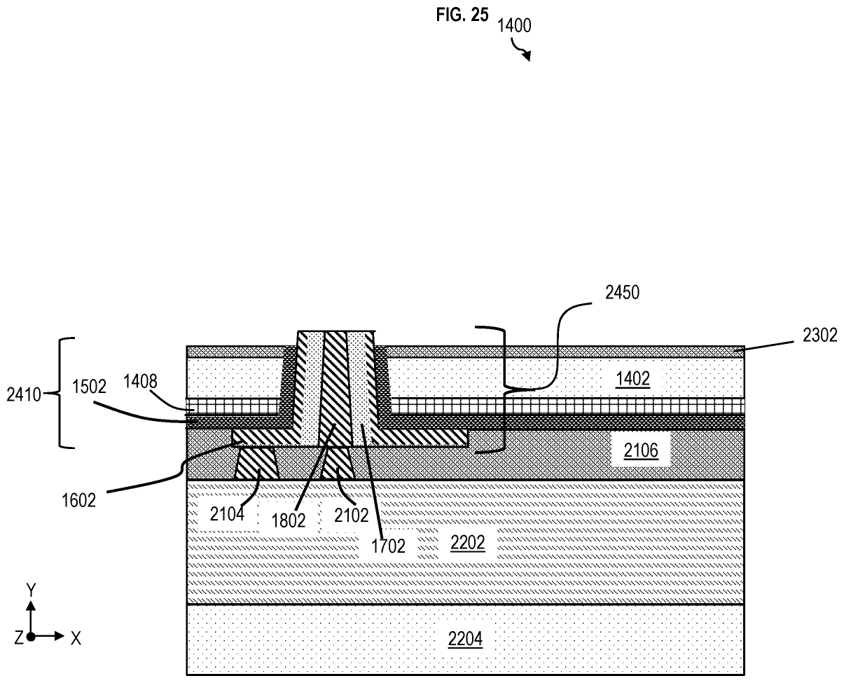

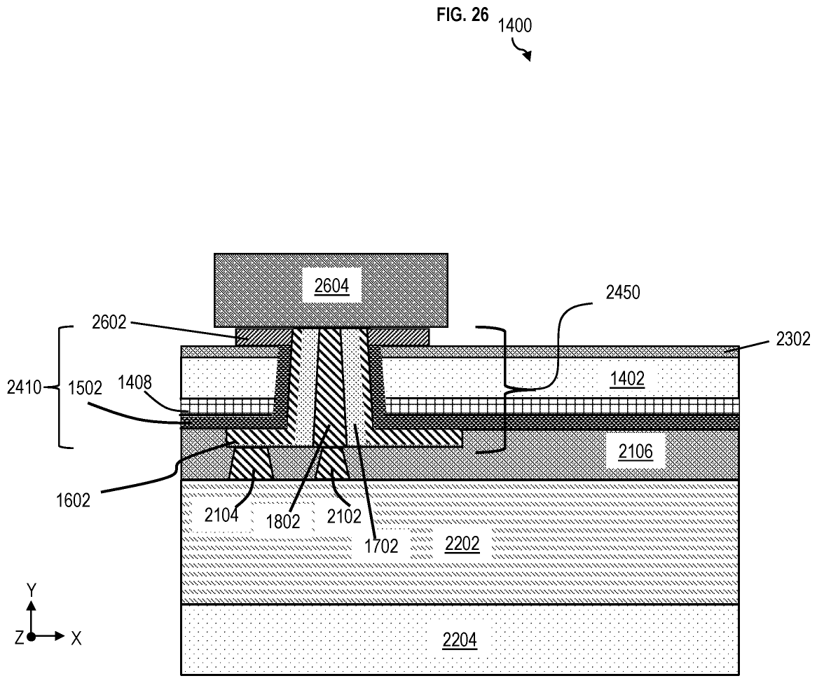

FIG. 25 depicts a cross-sectional view of the IC 1400 after selective dielectric recess to expose sidewalls of the copper cladding. The dielectric layer 2302 is selectively etched to expose the sidewalls of the outer conductor 2410 in preparation for the formation of the bottom contact 2602 depicted in FIG. 26.

FIG. 26 depicts a cross-sectional view of the IC 1400 after metal deposition, planarization, coaxial TIV footing patterning, and subtractive metal etch. A metal layer is deposited, and planarization is performed to expose one end of the coaxial via 2450. The metal layer is in contact with the outer conductor 2410 in order to eventually serve as a bottom contact. A hardmask layer 2604 is deposited and patterned. The material of the hardmask layer 2604 can include any suitable materials including materials discussed for hardmask layers 2002 and 1410. Using lithography, the pattern of the hardmask layer 2604 is utilized to etch the deposited metal layer into a bottom contact 2602 (e.g., second contact), where the bottom contact 2602 serves as a through silicon via bottom footing on the dielectric layer 2302 after portions of the metal layer have been removed. In one or more embodiments, a damascene process may be utilized to form the bottom contact 2602 instead of a subtractive metal etch.

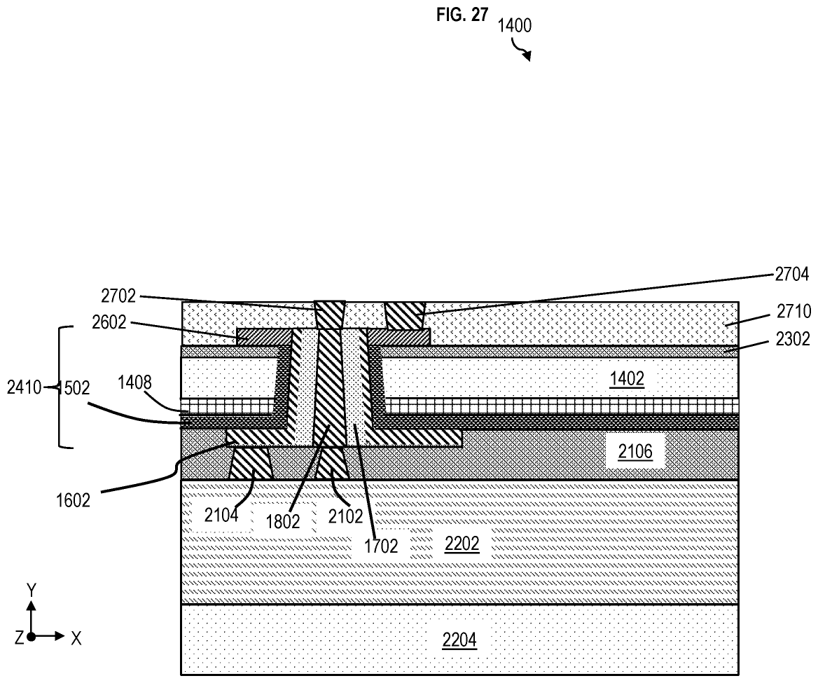

FIG. 27 depicts a cross-sectional view of the IC 1400 after hardmask removal, additional dielectric layer fill, and conductive via formation. The hardmask layer 2604 is removed. Dielectric material of the dielectric layer 2710 is deposited, planarization is formed, and openings (exposing the inner conductor 1802 and the bottom contact 2602) are etched through the dielectric layer 2710, using lithography. Metal is deposited to fill the openings, and etch back is performed, resulting in conductive via 2702 in contact with the inner conductor 1802 and conductive via 2704 in contact with the bottom contact 2602. Although one conductive via 2704 is shown on the bottom contact 2602, another conductive via 2704 can be formed on the bottom contact 2602 on the other side of the conductive via 2702. Example metals of conductive via 2702 and conductive via 2704 can include any of the metals discussed herein for the inner conductor 1802, outer conductor 2410, and metal layer 1602.

It is noted that the outer conductor 2410 has a small dimension in the x-axis. In one or more embodiments, the thickness of the outer conductor 2410 in the x-axis can be about 10 nanometers (nm), 15 nm, 20 nm, 30 nm, 50 nm, etc. In one or more embodiments, the thickness of the outer conductor 2410 can range from about 10-100 nm. The small dimension of the outer conductor 2410 may present a challenge to form a conductive via on the surface of the outer conductor 2410, and therefore, forming the metal layer to be the bottom contact 2602 for conductive via 2704 addresses this issue, as discussed herein.

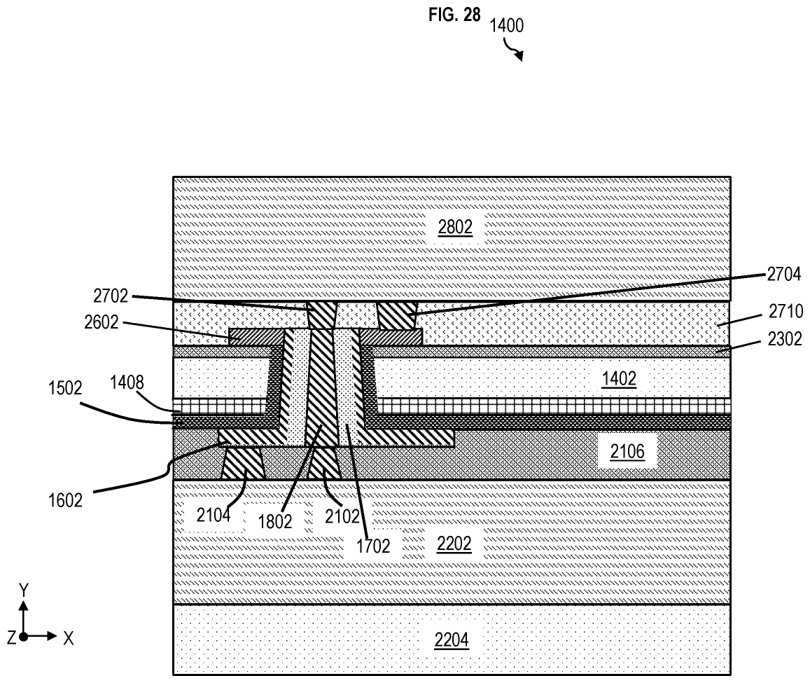

FIG. 28 depicts a cross-sectional view of the IC 1400 after device layer attachment. Using suitable techniques, a device layer 2802 is attached to the surface on one side of the IC 1400. The device layer 2802 can include various devices and interconnects as understood by one of ordinary skill in the art. In one or more embodiments, there can be passive or active devices (not shown) in and/or on the silicon layer (e.g., the substrate 1402) through which the coaxial via 2450 is formed. In one or more embodiments, the substrate 1402 can be a device layer having one or more passive and/or active devices. Also, there can be one or more metal interconnect layers that are stacked on top of the coaxial via 2450, which interpose between the coaxial via 2450 and another chip or package that is joined to it.

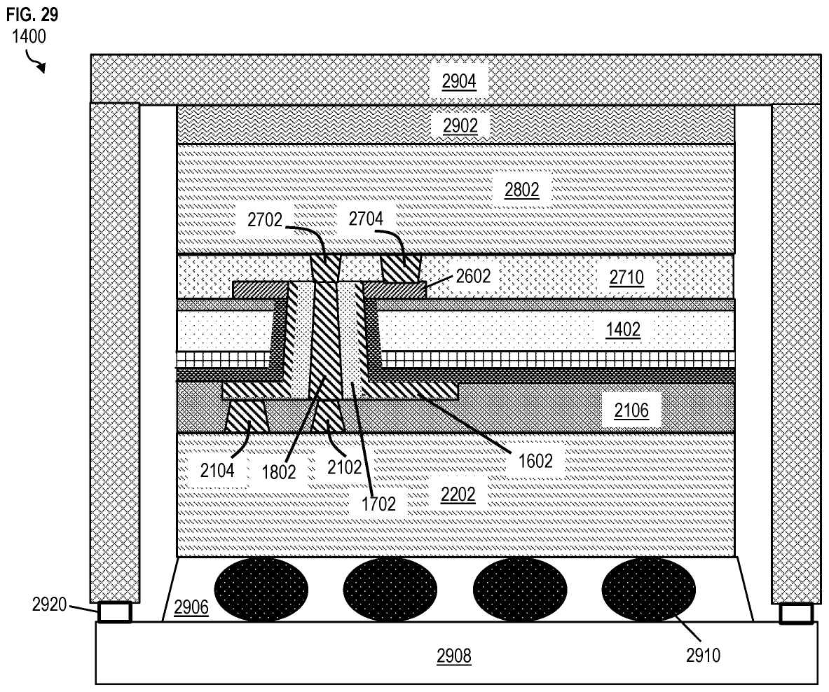

FIG. 29 depicts a cross-sectional view of the IC 1400 after controlled collapse chip connection (C4) bump formation, package attachment, carrier detachment, and lid attachment. The carrier 2204 is detached. A C4 bump layer 2906 of C4 bumps 2910 are attached to the device layer 2202, and a package 2908 is attached to the C4 bumps 1310. The C4 bumps can include soldering material. The package 2908 can include a printed circuit board. The C4 bumps and package can be part of a flip chip package. A thermal interface material 2902 can be in between the device layer 2802 and a lid 2904. A seal band 2920 can be utilized as an adhesive to seal the lid 2904 to the periphery of the package 2908.

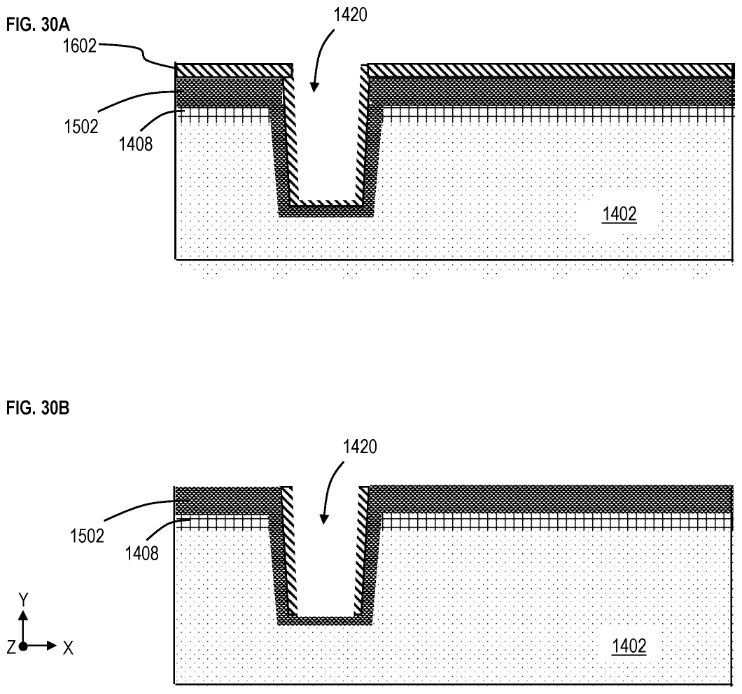

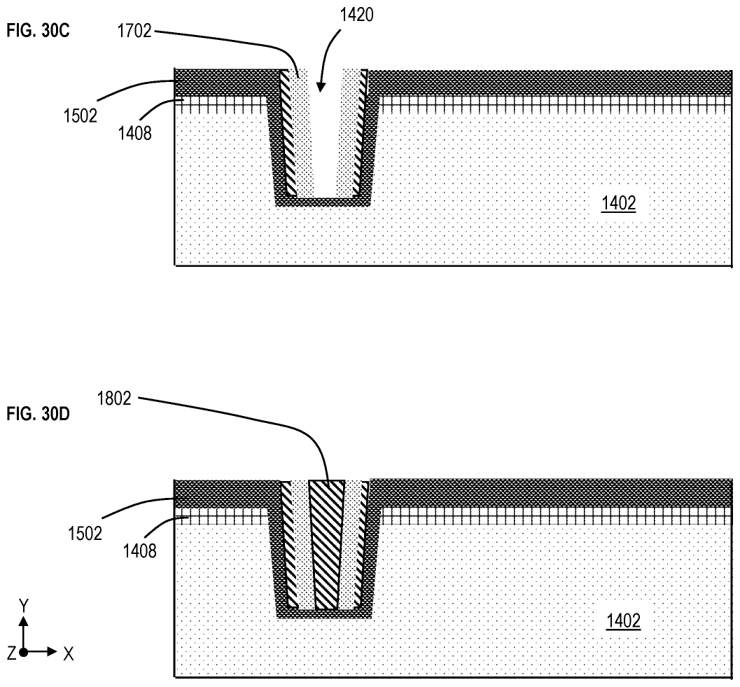

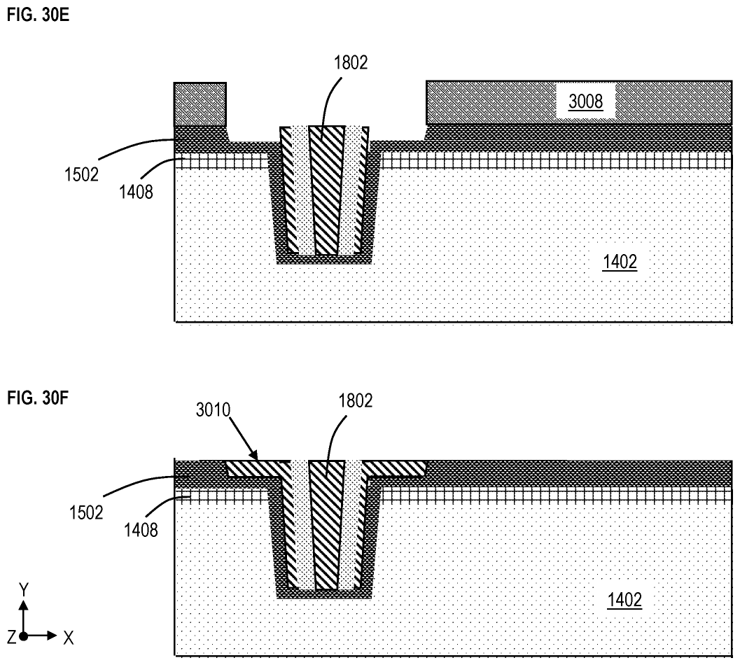

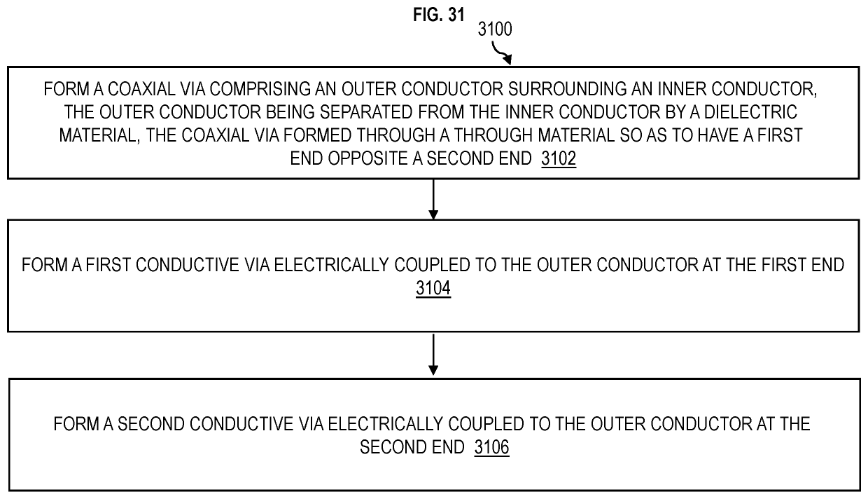

Subtractive etching has been illustrated in some embodiments. In accordance with one or more embodiments, a damascene process may be utilized for making the ground shielding contact. As such, FIGS. 30A, 30B, 30C, 30D, 30E, and 30F depict an example damascene process for making the ground shielding contact. FIG. 30A is analogous to FIG. 16. In FIG. 30A, metal of the metal layer 1602 has been deposited on the dielectric layer 1502. The metal layer 1602 can include any suitable materials including copper, aluminum, gold, etc. The metal layer 1602 on the sidewalls of the cavity 1420 will serve as the material for the outer conductor. FIG. 30B depicts the etch of the metal layer 1602. FIG. 30C depicts deposition of the dielectric layer 1702 with etch back. FIG. 30D depicts metal fill and planarization resulting in the inner conductor 1802. FIG. 30E depicts patterning and selective dielectric recess. A hardmask layer 3008 is deposited and patterned. The pattern of the hardmask layer 3008 is utilized to selectively etch the dielectric layer 1502. After removal of the hardmask layer 3008, FIG. 30F depicts metal fill and planarization resulting in the top contact 3010 analogous to the top contact 2010 in FIG. 20.

For the IC 100 and 1400, it should be appreciated that the subtractive process and/or damascene process can be utilized to form contacts (e.g., top contacts 510 and 2010 and/or bottom contacts 1010 and 2602) with subtractive and/or damascene sidewall contacts to the shielding layer (e.g., outer conductor 202 and 2410). This results in a sidewall angle of greater than or less than 90 degrees for a metal feature, depending on whether it is a subtractive feature or a damascene feature. In one or more embodiments, a first side of a coaxial via may be formed with a subtractive feature (e.g., top contact (or bottom contact)) and the other side with damascene feature (e.g., bottom contact (or top contact), or vice versa (with respect to the package orientation). In one or more embodiments, the first side and the other side of the coaxial via for the IC 100 and 1400 may be formed the same metal feature (e.g., both sides with a subtractive feature or both sides with a damascene feature).

FIG. 31 depicts a flowchart of a method 3100 of forming a coaxial via according to one or more embodiments. Reference can be made to any of the figures discussed herein. At block 3102, the method 3100 includes forming a coaxial via (e.g., coaxial vias 450 and 2450) comprising an outer conductor (e.g., outer conductors 202 and 2410) surrounding an inner conductor (e.g., inner conductors 402 and 1802), the outer conductor being separated from the inner conductor by a dielectric material (e.g., dielectric layers 302 and 1702), the coaxial via formed through a through material so as to have a first end opposite a second end. At block 3104, the method 3100 includes forming a first conductive via (e.g., conductive vias 604 and 2104) electrically coupled to the outer conductor at the first end. At block 3106, the method 3100 includes forming a second conductive via (e.g., conductive vias 1104 and 2704) electrically coupled to the outer conductor at the second end.

Further, a first contact (e.g., top contacts 510, 2010, and 3010) connects the first conductive via (e.g., conductive vias 604 and 2104) to the outer conductor at the first end. The first contact (e.g., top contacts 510 and 2010) extends laterally from the outer conductor. A second contact (e.g., bottom contacts 1010 and 2602) connects the second conductive via (e.g., conductive vias 1104 and 2704) to the outer conductor at the second end. The second contact (e.g., bottom contacts 1010 and 2602) extends laterally from the outer conductor. The through material comprises at least one dielectric material (e.g., dielectric layer 106), thereby forming the coaxial via as a through insulator via (TIV). The through material comprises a semiconductor material (e.g., substrate 1402) sandwiched by dielectric materials (e.g., dielectric layers 2106, 2302, and 2710), thereby forming the coaxial via as a through silicon via (TSV).

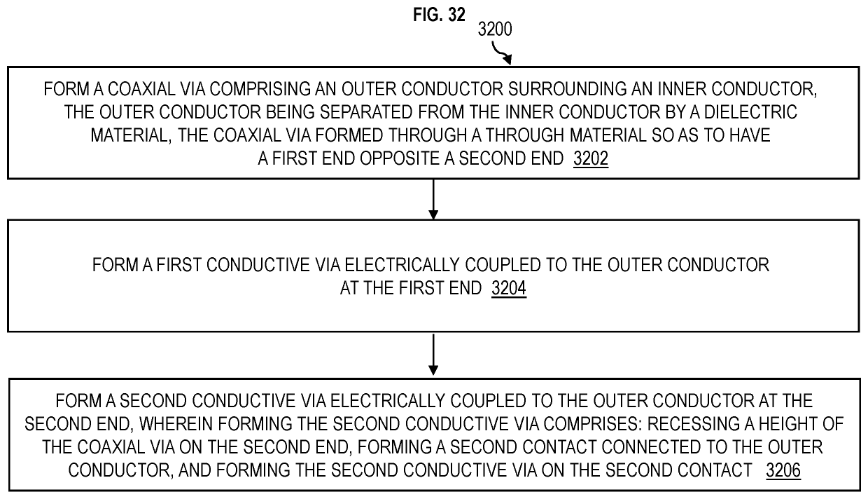

FIG. 32 depicts a flowchart of a method 3200 of forming a coaxial via according to one or more embodiments. Reference can be made to any of the figures discussed herein. At block 3202, the method 3200 includes forming a coaxial via (e.g., coaxial vias 450 and 2450) comprising an outer conductor (e.g., outer conductors 202 and 2410) surrounding an inner conductor (e.g., inner conductors 402 and 1802), the outer conductor being separated from the inner conductor by a dielectric material (e.g., dielectric layers 302 and 1702), the coaxial via formed through a through material so as to have a first end opposite a second end. At block 3204, the method 3200 includes forming a first conductive via (e.g., conductive vias 604 and 2104) electrically coupled to the outer conductor at the first end by a first contact (e.g., top contacts 510, 2010, and 3010). At block 3206, the method 3200 includes forming a second conductive via (e.g., conductive vias 1104 and 2704) electrically coupled to the outer conductor at the second end, wherein forming the second conductive via (e.g., conductive vias 1104 and 2704) comprises: recessing a height of the coaxial via on the second end, forming a second contact (e.g., bottom contacts 1010 and 2602) connected to the outer conductor, and forming the second conductive via (e.g., conductive vias 1104 and 2704) on the second contact.

Further, the first contact (e.g., top contacts 510, 2010, and 3010) connects the first conductive via (e.g., conductive vias 604 and 2104) to the outer conductor (e.g., outer conductors 202 and 2410) at the first end. The first contact (e.g., top contacts 510, 2010, and 3010) extends laterally from the outer conductor. The second contact (e.g., bottom contacts 1010 and 2602) extends laterally from the outer conductor (e.g., outer conductors 202 and 2410). The through material comprises at least one dielectric material (e.g., dielectric layer 106), thereby forming the coaxial via as a through insulator via (TIV). The through material comprises a semiconductor material (e.g., substrate 1402) sandwiched by dielectric materials (e.g., dielectric layers 2106, 2302, and 2710), thereby forming the coaxial via as a through silicon via (TSV).

In addition to gold, aluminum, and copper, the metals discussed herein can include ruthenium (Ru), tungsten (W), tungsten cobalt, nickel (Ni), titanium (Ti), molybdenum (Mo), etc., along with any combination thereof.

In one or more embodiments, dielectric material can be SiO₂, SiN, a low-k dielectric material or an ultra-low-k dielectric material. Low-k dielectric materials may generally include dielectric materials having a k value of about 3.9 or less. The ultralow-k dielectric material generally includes dielectric materials having a k value less than 2.5. Unless otherwise noted, all k values mentioned in the present application are measured relative to a vacuum. Exemplary ultra-low-k dielectric materials generally include porous materials such as porous organic silicate glasses, porous polyamide nanofoams, silica xerogels, porous hydrogen silsequioxane (HSQ), porous methylsilsesquioxane (MSQ), porous inorganic materials, porous CVD materials, porous organic materials, or combinations thereof. The ultra-low-k dielectric material can be produced using a templated process or a sol-gel process as is generally known in the art. In the templated process, the precursor typically contains a composite of thermally labile and stable materials. After film deposition, the thermally labile materials can be removed by thermal heating, leaving pores in the dielectric film. In the sol gel process, the porous low-k dielectric films can be formed by hydrolysis and polycondensation of an alkoxide(s) such as tetraetehoxysilane (TEOS).

Various embodiments of the present disclosure are described herein with reference to the related drawings. Alternative embodiments can be devised without departing from the scope of this disclosure. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The phrase “selective to,” such as, for example, “a first element selective to a second element,” means that the first element can be etched and the second element can act as an etch stop.

As used herein, “p-type” refers to the addition of impurities to an intrinsic semiconductor that creates deficiencies of valence electrons. In a silicon-containing substrate, examples of p-type dopants, i.e., impurities, include but are not limited to: boron, aluminum, gallium and indium.

As used herein, “n-type” refers to the addition of impurities that contributes free electrons to an intrinsic semiconductor. In a silicon containing substrate examples of n-type dopants, i.e., impurities, include but are not limited to antimony, arsenic and phosphorous.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present disclosure will now be provided. Although specific fabrication operations used in implementing one or more embodiments of the present disclosure can be individually known, the described combination of operations and/or resulting structures of the present disclosure are unique. Thus, the unique combination of the operations described in connection with the fabrication of a semiconductor device according to the present disclosure utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

As noted above, atomic layer etching processes can be used in the present disclosure for via residue removal, such as can be caused by via misalignment. The atomic layer etch process provide precise etching of metals using a plasma-based approach or an electrochemical approach. The atomic layer etching processes are generally defined by two well-defined, sequential, self-limiting reaction steps that can be independently controlled. The process generally includes passivation followed selective removal of the passivation layer and can be used to remove thin metal layers on the order of nanometers. An exemplary plasma-based approach generally includes a two-step process that generally includes exposing a metal such a copper to chlorine and hydrogen plasmas at low temperature (below 20° C.). This process generates a volatile etch product that minimizes surface contamination. In another example, cyclic exposure to an oxidant and hexafluoroacetylacetone (Hhfac) at an elevated temperature such as at 275° C. can be used to selectively etch a metal such as copper. An exemplary electrochemical approach also can include two steps. A first step includes surface-limited sulfidization of the metal such as copper to form a metal sulfide, e.g., Cu₂S, followed by selective wet etching of the metal sulfide, e.g., etching of Cu₂S in HCl. Atomic layer etching is relatively recent technology and optimization for a specific metal is well within the skill of those in the art. The reactions at the surface provide high selectivity and minimal or no attack of exposed dielectric surfaces.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The photoresist can be formed using conventional deposition techniques such chemical vapor deposition, plasma vapor deposition, sputtering, dip coating, spin-on coating, brushing, spraying and other like deposition techniques can be employed. Following formation of the photoresist, the photoresist is exposed to a desired pattern of radiation such as X-ray radiation, extreme ultraviolet (EUV) radiation, electron beam radiation or the like. Next, the exposed photoresist is developed utilizing a conventional resist development process.

After the development step, the etching step can be performed to transfer the pattern from the patterned photoresist into the interlayer dielectric. The etching step used in forming the at least one opening can include a dry etching process (including, for example, reactive ion etching, ion beam etching, plasma etching or laser ablation), a wet chemical etching process or any combination thereof.

For the sake of brevity, conventional techniques related to making and using aspects of the disclosure may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

In some embodiments, various functions or acts can take place at a given location and/or in connection with the operation of one or more apparatuses or systems. In some embodiments, a portion of a given function or act can be performed at a first device or location, and the remainder of the function or act can be performed at one or more additional devices or locations.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The present disclosure has been presented for purposes of illustration and description but is not intended to be exhaustive or limited to the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

The diagrams depicted herein are illustrative. There can be many variations to the diagram or the steps (or operations) described therein without departing from the spirit of the disclosure. For instance, the actions can be performed in a differing order or actions can be added, deleted or modified. Also, the term “coupled” describes having a signal path between two elements and does not imply a direct connection between the elements with no intervening elements/connections therebetween. All of these variations are considered a part of the present disclosure.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e., one, two, three, four, etc. The terms “a plurality” are understood to include any integer number greater than or equal to two, i.e., two, three, four, five, etc. The term “connection” can include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A semiconductor structure comprising:
a through material;
a coaxial via comprising an outer conductor surrounding an inner conductor, the outer conductor being separated from the inner conductor by a dielectric material, the coaxial via being formed through the through material so as to have a first end opposite a second end;
a first contact connected to the outer conductor at the first end; and
a second contact connected to the outer conductor at the second end.

2. The semiconductor structure of claim 1, wherein the first contact connects to a first conductive at the first end.

3. The semiconductor structure of claim 1, wherein the first contact extends laterally from the outer conductor.

4. The semiconductor structure of claim 1, wherein a second contact connects to a second conductive via at the second end.

5. The semiconductor structure of claim 1, wherein the second contact extends laterally from the outer conductor.

6. The semiconductor structure of claim 1, wherein the through material comprises at least one dielectric material, thereby forming the coaxial via as a through insulator via (TIV).

7. The semiconductor structure of claim 1, wherein the through material comprises a semiconductor material sandwiched by dielectric materials, thereby forming the coaxial via as a through silicon via (TSV).

8. A method comprising:
forming a coaxial via comprising an outer conductor surrounding an inner conductor, the outer conductor being separated from the inner conductor by a dielectric material, the coaxial via being formed through a through material so as to have a first end opposite a second end;
forming a first contact connected to the outer conductor at the first end; and
forming a second contact connected to the outer conductor at the second end.

9. The method of claim 8, wherein the first contact connects to a first conductive at the first end.

10. The method of claim 8, wherein the first contact extends laterally from the outer conductor.

11. The method of claim 8, wherein a second contact connects to a second conductive via at the second end.

12. The method of claim 8, wherein the second contact extends laterally from the outer conductor.

13. The method of claim 8, wherein the through material comprises at least one dielectric material, thereby forming the coaxial via as a through insulator via (TIV).

14. The method of claim 8, wherein the through material comprises a semiconductor material sandwiched by dielectric materials, thereby forming the coaxial via as a through silicon via (TSV).

15. The method of claim 11, wherein the second conductive via is formed by: recessing a height of the coaxial via on the second end, forming the second contact connected to the outer conductor, and forming the second conductive via on the second contact.

16. A semiconductor structure comprising:
a through material;
a coaxial via comprising an outer conductor surrounding an inner conductor, the outer conductor being separated from the inner conductor by a dielectric material, the coaxial via being formed through the through material so as to have a first end opposite a second end;
a first conductive via electrically coupled to the outer conductor at the first end, wherein the first conductive via electrically couples the coaxial via to a device layer; and
a second conductive via electrically coupled to the outer conductor at the second end.

17. The semiconductor structure of claim 16, wherein the second conductive via electrically couples the coaxial via to another device layer, the another device layer being opposite the device layer.

18. The semiconductor structure of claim 16, wherein a first contact connects the first conductive via to the outer conductor at the first end, the first contact and the outer conductor forming a continuous piece as a ground shielding.

19. The semiconductor structure of claim 16, wherein a second contact connects the second conductive via to the outer conductor at the second end, the second contact and the outer conductor forming a continuous piece as a ground shielding.

20. The semiconductor structure of claim 16, wherein:
the through material comprises at least one dielectric material, thereby forming the coaxial via as a through insulator via (TIV); or
the through material comprises a semiconductor material sandwiched by dielectric materials, thereby forming the coaxial via as a through silicon via (TSV).
